(19) United States
(12) Patent Application Publication
(10) Pub. No.: US 2024/0128720 A1
(43) Pub. Date: Apr. 18, 2024

(54) Meta-optics Integrated on VCSELs

(71) Applicant: AMS SENSORS ASIA PTE. LTD., Singapore (SG)

(72) Inventors: Serdal OKUR, Lawrence Township, NJ (US); Xu ZHANG, Claymont, DE (US); Wei Ting CHEN, Cambridge, MA (US); Jean-Francois SEURIN, Princeton Junction, NJ (US)

(21) Appl. No.: 18/546,299

(22) PCT Filed: Dec. 20, 2021
(86) PCT No.: PCT/SG2021/050804

§ 371 Date: Aug. 14, 2023

(30) Foreign Application Priority Data
Feb. 15, 2021 (GB) 2102104.3

(51) Int. Cl. H01S 5/183; H01S 5/42

(52) U.S. Cl. CPC H01S 5/18308; H01S 5/18341; H01S 5/426

(57) ABSTRACT

There is provided an array of light emitting elements integrated with meta-surfaces. The meta-surfaces are constructed from a semiconductor alloy comprising at least two different semiconductors. The composition of the semiconductor can be varied so as to provide different refractive indices. A method of manufacture of such an array is also provided.

### CROSS-REFERENCE TO RELATED APPLICATION(S)

This is the U.S. national stage of application No. PCT/SG2021/050804, filed on Dec. 20, 2021, and priority under 35 U.S.C. § 119(a) and 35 U.S.C. § 365(b) is claimed from GB Patent Application No. 2102104.3, filed on Feb. 15, 2021; the disclosures of which are incorporated herein by reference.

### FIELD

The present disclosure relates to a meta-optic array and a method of manufacturing the same.

### BACKGROUND

A problem with conventional optical lenses is that they may be bulky, expensive, and require grinding, polishing or molding to manufacture. These processes are not compatible to the manufacturing of semiconductor devices. For this reason, structures in the form of meta-surfaces are proving to be very attractive alternatives, and are becoming increasingly prevalent in optical systems. Metamaterials are artificially engineered effective media comprising sub-wavelength elements. Metasurfaces are two dimensional metamaterials, which are typically based on a single-layer metallic or dielectric pattern. FIG. 1 is a perspective diagram of a meta-surface 100 illustrating a plurality of nano-pillars 101. Sub-wavelength elements in a meta-surface may be arranged periodically, quasi-periodically, or randomly, they may have regular or irregular shapes, and they may be defined by, for example, raised portions of a substrate, by depressions (holes), or by changes in refractive index.

Optical meta-surfaces are sub-wavelength patterned layers that interact strongly with light and can dramatically after the properties of light over a subwavelength thickness. Whereas conventional optics is based on light refraction and propagation effects, optical meta-surfaces provide a fundamentally different method of light manipulation based on the interference of scattered light from small nanostructures. These nanostructures resonantly capture the light and re-emit it with a defined phase, polarization, amplitude and spectrum, enabling sculpting of light waves with unprecedented accuracy.

A meta-surface based flat lens is known in the art as a ‘meta-lens’. A meta-lens may be configured, for example, to operate as a convex lens, a concave lens, a prism, or be configured to alter a phase of incident radiation, or the like.

Vertical Cavity Surface Emitting Lasers (VCSELs) are highly versatile light sources. They are used in many applications such as facial recognition, sensing, 3D printing, LIDAR and optical communications. The advantageous features of VCSELs are their circular beam profile and low power consumption. Furthermore, unlike edge emitting lasers, which may only be tested at the end of the manufacturing process, VCSELs can be tested at intermediate stages in the manufacturing process, for both material quality and processing issues. Checks can be made for example, that vias, the electrical connections between layers of a circuit, have not been completely cleared of dielectric material during etching. An interim testing can check whether the top metal layer is making contact to the initial metal layer.

Another important advantage of VCELS is that because they emit the beam perpendicular to the active region of the laser as opposed to parallel as with an edge emitter, tens of thousands of VCSELs can be processed simultaneously on a wafer. Although the VCSEL production process is more labor and material intensive, the yield is more predictable.

The wafer manufacture of VCSELs makes them very suitable for the addition of further integrated optical components using a wafer level fabrication process. VCSELs are used in a variety of applications, ranging from facial recognition, sensing, and optical communications, among others. An example of this is inclusion of integrated lenses on VCSELs, as disclosed in U.S. Pat. No. 73,535,949. FIG. 2 is a cross sectional diagram of a VCSEL array illustrating its use as an illumination device 200. The device comprises a plurality of VCSELS 201 on a substrate 202, and has a micro-lens array 203 to receive and deflect the light 204 emitted by the VCSELs. Regions of the micro-lens array have different offsets relative to the light emitters, resulting in the generation of multiple sub-beams with different angles of deflection. The multiple sub-beams combine to form the divergent illumination beam 205. Similar devices are disclosed in U.S. Pat. No. 6,888,871, which discloses VCSELs with integrated microlenses, and US 20080096298 which discloses a VCSEL with a self-forming microlens. The integration of a VCSEL array with microlenses for use in optical scanning is disclosed in EP1317038. A further application is structured illumination, which is a technique that involves projecting a known pattern of light onto a scene. The structured illumination may have any regular shape, such as lines or circles, or may have a pseudo-random pattern. A light pattern created by structured illumination makes it possible to distinguish objects according to their distance from the light emitter. WO2020022960 discloses a structured light projector which using an integrated meta-lens.

Meta-optics are highly suitable for combining with VCSELs, since the addition of meta-materials can be easily combined with the same wafer manufacture techniques of lithography and etching used for VCSEL arrays. However, passive meta-optics on VCSELs are limited in their ability to manipulate the frequency and amplitude responses of the incident electromagnetic waves in a variable manner due to their constant refractive index. Different approaches have been used to tune meta-optics via manipulating the refractive index of meta-surface material. To date, the most common techniques for a tunable refractive index of meta-surfaces are administered by applied electric field or laser pulse. These techniques are discussed in Zhang, Jin, et al. “Electrically tunable metasurface with independent frequency and amplitude modulations.” ACS Photonics 7.1 (2019): 265-271, and Zou, Chengjun, Isabelle Staude, and Dragomir N. Neshev. “Tunable metasurfaces and metadevices.” Dielectric Metamaterials, Woodhead Publishing, 2020. 195-222.

Temperature, magnetic field, pressure, or strain are less common methods to tune a meta-element's refractive index. All these techniques are required to have an external stimulus to meta-optics. Various other methods for altering the electromagnetic responses of meta-surfaces are also used to achieve tunable functionalities. For instance, PIN diodes and varactors are embedded into active meta-elements and electrically controlled. However, none of these works addresses the requirement of efficient and low-cost tuning which is very important for practical applications, especially for ones integrated to VCSELs.

### SUMMARY

According to a first aspect of the present disclosure there is provided a light emitting or detecting element comprising a meta-surface, wherein the meta-surface comprises a semiconductor alloy of a first semiconductor and a second semiconductor. A composition defines relative amounts of the first semiconductor and the second semiconductor in the alloy. The semiconductor alloy has a first composition.

Embodiments of the present disclosure addresses the above-mentioned issues by providing a new technique to achieve low-cost passive meta-optics integrated on light emitting or detecting elements with adjustable refractive index and different optical functionalities based on meta-surface geometry. Embodiments of the present disclosure solves the problem of how to manipulate the frequency and amplitude responses of the incident electromagnetic waves in a meta-surface. The solution comprises changing the refractive index by varying the composition of a semi-conductor alloy used to form the metasurface.

In an embodiment, the first semiconductor is Silicon and the second semiconductor is Germanium.

In an embodiment, the first semiconductor is one of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (PbSe), Tellurium Selenide (TeSe), or Gallium Arsenide (GaAs), and wherein the second semiconductor is another of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (PbSe), Tellurium Selenide (TeSe), or Gallium Arsenide (GaAs), the second semiconductor being different from the first semiconductor. The selection of semiconductors allows a variation of refractive index across an appropriate range for different wavelengths of light, leading to tunable dispersion properties.

In an embodiment, the semiconductor alloy comprises a third semiconductor and the first composition defines the relative amounts of the first semiconductor, second semiconductor and third semi-conductor in the alloy. The provision of a third semiconductor improves the possible range of wavelengths and refractive indices.

In an embodiment, the third semiconductor is one of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (PbSe), Tellurium Selenide (TeSe), or Gallium Arsenide (GaAs), and wherein the third semiconductor is different from the first semiconductor and the second semiconductor.

In an embodiment, the light emitting element comprising a vertical cavity surface emitting laser. The vertical cavity surface emitting lasers is extremely well suited to wafer manufacture technique which can be used to create meta-surfaces.

In an embodiment, there is provided a light emitting array comprising a plurality of light emitting elements according to previous embodiments. Arrays allow the use of the arrangement of previous embodiments to be used for applications such as flood illumination.

In an embodiment a first light emitting element and at least one second light emitting element having a second composition different from the first composition. This allows the formation of beams and structured illumination.

The following embodiments provide different options so as to flexibly apply the techniques of the present disclosure to a maximum number of applications.

In an embodiment, the light emitting elements of the plurality of light emitting elements are spaced along a first direction, and the respective compositions vary along the first direction.

In an embodiment the respective compositions vary such that at least a proportion of one semiconductor in the alloy varies linearly along the first direction.

In an embodiment, the light emitting elements have a uniform composition.

In an embodiment, the light emitting array comprises a plurality of regions, wherein each region comprises light emitting elements with metasurfaces with a single composition, wherein the composition in each region is different to compositions in other regions.

In an embodiment, the light emitting array is configured to enable each region to operate at different times.

In an embodiment, the regions are configured to provide structured illumination onto a pre-defined scene.

In an embodiment, the regions are configured to provide illumination for facial recognition.

A second aspect provides a simple and cost effective method of manufacturing elements and arrays according to above embodiments.

According to the second aspect, there is provided a method of manufacturing a light emitting element with a meta-surface, the method comprising the steps of: using chemical vapour deposition to apply a layer of semiconductor alloy, wherein the semiconductor alloy comprises a first semiconductor and a second semiconductor, and wherein a composition defines relative amounts of the first semiconductor and the second semiconductor in the alloy, and wherein the semiconductor alloy has a first composition, and fabricating a meta-surface in the alloy.

In an embodiment, the method further comprises manufacturing a light emitting array comprising a plurality of light emitting elements. Each light emitting element comprises a meta-surface. The method further comprises: prior to the step of using chemical vapour deposition to apply a layer of semiconductor alloy, masking one or more light emitting element in the array, after using chemical vapour deposition to apply the layer of semiconductor alloy, and unmasking the masked one or more light emitting elements. The method further comprises masking one or more of previous unmasked light emitting element in the array, applying a second semiconductor alloy with a second composition different from the first composition, unmasking the masked light emitting elements, and fabricating a meta-surface in the alloy.

In an embodiment, the method further comprises dividing the light emitting array into a plurality of regions, selecting for each region a semiconductor alloy with a composition, wherein each region is assigned a semiconductor alloy comprising a composition different from every other region, and for each region: masking light emitting elements which are not in the region, using chemical vapour deposition to apply the layer of semiconductor alloy to light emitting elements in the region, and unmasking the elements not in the region. A metasurface is then fabricated in the semiconductor alloy.

In an embodiment, the first semiconductor is one of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (PbSe), Tellurium Selenide (TeSe), or Gallium Arsenide (GaAs), and the second semiconductor is another of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (PbSe), Tellurium Selenide (TeSe), or Gallium Arsenide (GaAs). The second semiconductor is different from the first semiconductor.

In an embodiment, the semiconductor alloy comprises a third semiconductor.

In an embodiment, the third semiconductor is one of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (PbSe), Tellurium Selenide (TeSe), or Gallium Arsenide (GaAs). The third semiconductor is different from the first semiconductor and the second semiconductor.

In an embodiment, the method further comprises selecting regions such as to enable the light emitting array to provide structured illumination onto a pre-defined scene.

In an embodiment, the regions are selected such as to enable the light emitting array to provide structured illumination onto a pre-defined scene provide illumination for facial recognition.

In an embodiment, Metal Organic Chemical Vapour Deposition (MOCVD) may be used.

In an embodiment, Plasma Enhanced Chemical Vapour Deposition (PECVD) may be used.

In each of the above aspects and embodiments a light detecting element may be used instead of the light emitting element.

### BRIEF DESCRIPTION OF DRAWINGS

These and other aspects of the present disclosure will now be described, by way of example only, with reference to the accompanying drawings, which show:

FIG. 1: A schematic diagram showing an example of a meta-surface structure;

FIG. 2: A schematic diagram showing an example of the formation of a beam using a known microlens array;

FIG. 3: A cross sectional diagram of a light emitting element with a meta-surface, according to an embodiment of the present disclosure;

FIG. 4: A cross sectional diagram of a light emitting element array of VCSELs with meta-surfaces, according to an embodiment of the present disclosure;

FIG. 5: A representation of a light emitting element array according to an embodiment of the present disclosure;

FIG. 6: A representation of a light emitting element array according to another embodiment of the present disclosure;

FIG. 7: A representation of a light emitting element array according to yet another embodiment of the present disclosure;

FIG. 8: A flowchart showing method of manufacture of a light emitting element according to an embodiment of the present disclosure;

FIG. 9: A flowchart showing method of manufacture of a light emitting element array according to an embodiment of the present disclosure;

FIG. 10: A flowchart showing method of manufacture of a light emitting element array according to an embodiment of the present disclosure; and

FIG. 11: A flowchart showing method of manufacture of a light emitting element array according to an embodiment of the present disclosure.

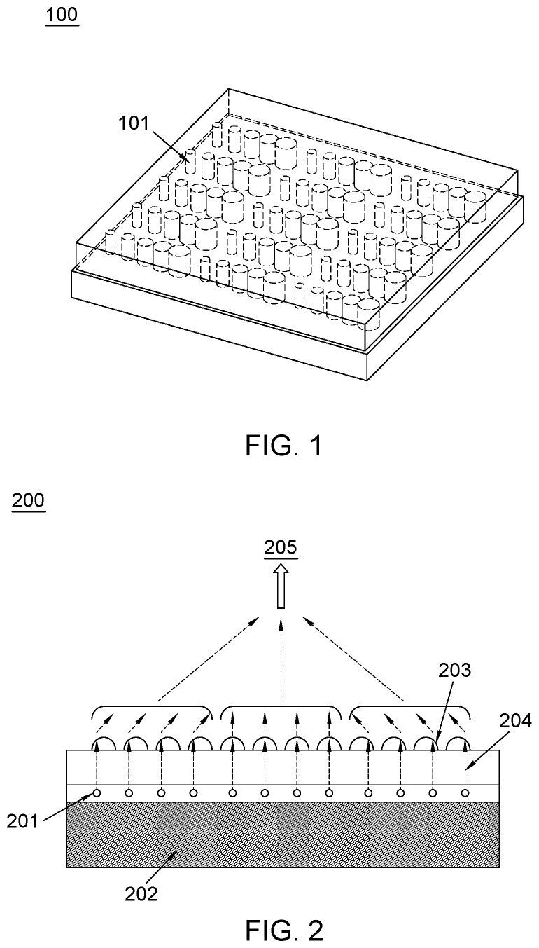

### DETAILED DESCRIPTION

The present disclosure provides a light emitting or detecting element and element array, wherein the elements each have a meta-surface, and a method of construction of such an arrangement, which address the problems which have been identified above. Embodiments of the present disclosure provide both an arrangement of meta-surfaces on the light emitting or detecting arrays with varying refractive index, and a growth technique that would mainly provide multiple static meta-surfaces, whose optical functionalities will be encoded at wafer level and will differ from each other.

In an embodiment, there is provided a single light emitting element comprising a meta-surface. The meta-surface comprises a semiconductor alloy of a first semiconductor and a second semiconductor. A composition is defined for the semiconductor, which defines the proportions of each semiconductor in the meta-surface. For example, in an embodiment a first semiconductor alloy might have a composition of 0.4 Silicon and a 0.6 Germanium, or any other composition of these two semiconductors or any of the semiconductor options identified below. The present disclosure is not limited to any combination of semiconductors or any particular composition. The composition may be written for example as GeₓSi₁₋ₓ, wherein x is the fraction of Germanium and 1−x is the fraction of Silicon. This applies with different semiconductor combinations, and with a third or more semiconductors in the composition. The composition defines relative amounts of the first semiconductor and the second semiconductor in the alloy. In embodiments where more than one alloy is used, a first semiconductor alloy has a first composition, and a second semiconductor alloy has a second composition, etc.

The selection of a specific composition provides for a required refractive index. Such an arrangement may be used in combination with any application requiring an optical meta-surface. The alloy comprises a first proportion which is a fraction of the alloy consisting of the first semiconductor and a second proportion a fraction of the alloy consisting of the second semiconductor. In an embodiment, the first semiconductor is one of silicon, germanium or selenium. The second semiconductor is another of silicon, germanium or tin, different from the first semiconductor.

The present disclosure takes advantage of the varying refractive index of semiconductor alloys as their composition varies. The respective proportions of the first semiconductor and the second semiconductor may be varied in order to achieve a required refractive index.

In an embodiment, an alloy of Silicon and Germanium is used. The present disclosure is not however limited to these two semiconductors. In other embodiments, Tin is used, either with one of Silicon or Germanium, or as an alloy with three semiconductors, providing further flexibility in design of a meta-surface. In an embodiment, the first semiconductor is one of silicon, germanium or tin. The second semiconductor is another of silicon, germanium or tin, different from the first semiconductor. In an embodiment, the alloy may be a composition of three semiconductors, wherein the proportions of the three different semiconductors are varied to provide different optical properties such as refractive index.

Data for the variation of the refractive index for different light frequencies and different compositions of Silicon Germanium alloy may be in Humlicek, J., Properties of Strained and Relaxed Silicon Germanium Ed. Kasper K., EMIS Datareviews Series, N12, INSPEC, London 1995 Chapters 4.6 and 4.7, pp 116-131.

In other embodiments, lead, tellurium, and selenium are used. This combination is typically used for longer wavelength applications. In embodiments, gallium arsenide is used in combination with other semiconductors. The person skilled in the art will appreciate that there are other semiconductors that can be used, with compositions of two or more semiconductors selected for suitability for a given application. The present disclosure is not limited to any given combination of semiconductors.

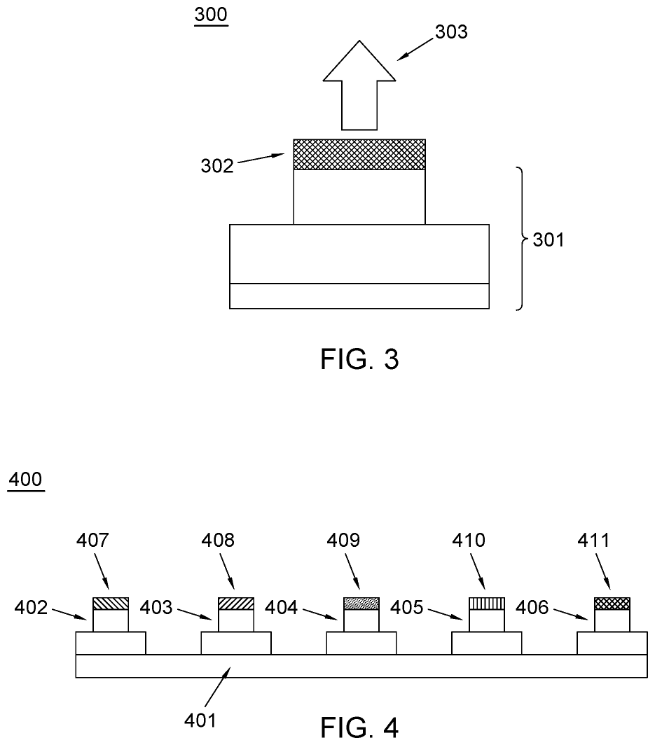

In an embodiment, the light emitting element is a Vertical Cavity Surface Emitting Laser (VCSEL). FIG. 3 is a schematic illustration of a single VCSEL arrangement 300 comprising a vertical cavity surface emitting laser, 301, configured to emit light 303 from a surface, and a meta-surface 302 according to an embodiment. The meta-surface 302 comprises an alloy comprising a first semiconductor and a second semiconductor. In an embodiment, the alloy comprises more than two semiconductors. The proportions of the semiconductors is selected in order to provide a required refractive index and may be used, for example, to provide a desired focal length.

In embodiments, arrays of light emitting elements with meta-surfaces are provided. In embodiments the light emitting element has a structure comprising a quantum well sandwiched between two reflecting layers e.g. DBRs (Distributed Bragg Reflectors). The optical meta-surface (which may also be referred to a as a meta-structure) may be in direct contact with the DBR. In implementations the optical meta-surface (meta-structure/nano-structure) has a refractive index of >2 at the operational wavelength, facilitated by use of a semiconducting material for the optical meta-surface (meta-structure). This is usefully close to that of the DBR.

In implementations the optical meta-surface (meta-structure) is located on top of the quantum well, with the latter sandwiched between DBRs. This is implemented without any modification to the either the quantum well or to the DBRs. Thus the optical meta-surface (meta-structure) does not extend into either the CDRs or quantum well. In embodiments, the respective metasurfaces are disposed on respective light emitting surfaces of the light emitting elements. This disposition of the metasurface may be combined with any of the described embodiments.

Such an array may be, for example, an array of VCSELs.

FIG. 4 is a cross-sectional view of a VCSEL array 400, each VCSEL comprising a meta-surface. Five VCSELs are illustrated, for simplicity. However, very much larger arrays are typical and the present disclosure is not limited to any given number of light emitting elements in an array. Likewise, the person skilled in the art will recognise that such an array of light emitting elements may comprise devices other than VCSELs, such as edge emitting lasers, light emitting diodes or light detecting elements. Referring to FIG. 4, each of the VCSELs 402, 403, 404, 405, 406, is located on substrate 401, has a respective meta-surface 407, 408, 409, 410, 411 comprising a different proportion of a first and a second semiconductor. In the example of FIG. 4, the first VCSEL has a meta-surface 407 comprising entirely of the first semiconductor. The second VCSEL 402 has a meta-surface 408 comprising a proportion of the first semiconductor equal to 0.75 and a proportion of the second semiconductor of 0.25. The third VCSEL has a meta-surface 409 comprising equal proportions of the first and second semiconductors. The fourth VCSEL has a meta-surface 410 comprising a proportion of the first semiconductor equal to 0.25 and a proportion of the second semiconductor of 0.75. The fifth VCSEL 405 has a meta-surface 411 comprising entirely of the second semiconductor. However, these details are just for illustration and, just as the present disclosure may include any number of light emitting elements in an array, any variation in the ratios of the first and second semiconductors is also possible and within the scope of the present disclosure. In an embodiment, there is a linear variation of the proportion of each semiconductor across the array. However, the present disclosure is not limited to this and non-linear variations, including bespoke patterns for applications such as facial recognition are possible in embodiments.

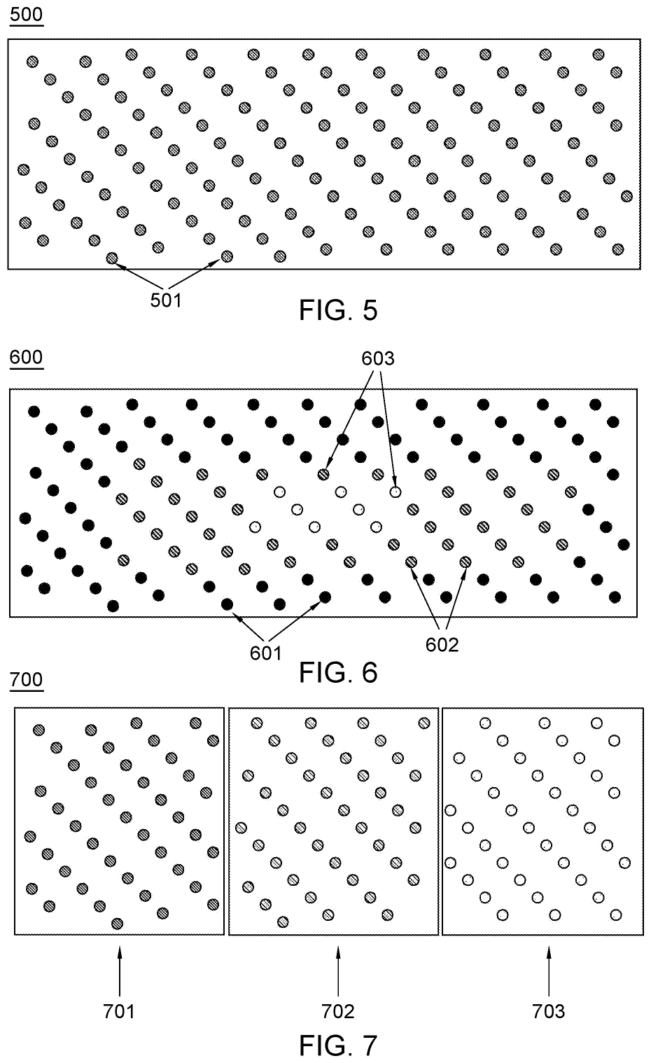

An example of a much larger array is illustrated in FIG. 5, which is a representation of the meta-surfaces in the array. Each dot 501 represents a light emitting element, with a meta-surface. In an embodiment, each of the light emitting elements is a VCSEL. However, such an array may be used with other light emitting devices. In the embodiment of FIG. 5, each of light emitting elements 500 in the array has the same proportion of each semiconductor in all its meta-surfaces, i.e. the meta-surfaces are uniform across the array. Any of the combinations of semiconductors previously described may be used in such an array. Each meta-surface 501 has the same composition of semiconductors, wherein the composition is determined by required optical properties. In an embodiment, the meta-optics have addressable functionality. Typically, each element operates at the same time.

In an embodiment, the light emitting element array may have meta-surfaces with different compositions. This arrangement is illustrated in FIG. 6, which is a diagram showing a representation of the light emitting elements in the array 600. As in FIG. 5, each dot represents a light emitting element with a meta-surface, each of which in an embodiment is a VCSEL. In the embodiment of FIG. 5, the semiconductor composition of the meta-surfaces varies. Any of the combinations of semiconductors previously described may be used in such an array. In FIG. 6, three different types of meta-surfaces, 601, 602, 603 are illustrated. Each of these types represents a different semiconductor composition. The number of types is only illustrative and the present disclosure may include any number of different types with different compositions and arranged in different patterns. The patterns may comprise a linear variation across the array, a non-linear variation, or a bespoke pattern for a given application. The present disclosure is not limited to any set pattern of composition variation in the proportions of the semiconductors used in the meta-optic elements. In an embodiment, the meta-optics have addressable functionality. This may be implemented, in an embodiment, by application of an electrical field to the meta-optics. Typically, each element operates at the same time.

In an embodiment, the light emitting element array may comprise regions, wherein each region has light emitting elements with meta-surfaces with the same composition of semiconductor alloy. The regions may be irregularly shaped or set in a pattern for a specific illumination purpose, such as structured illumination, e.g. facial recognition in the embodiment. In FIG. 6, an area comprising light emitting elements with meta-surfaces with the same composition of semiconductors may be regarded as regions. In an embodiment, the regions may be regularly shaped, as illustrated in regular as in the embodiment of FIG. 7. In an embodiment, each region comprises light emitting elements with metasurfaces with a single composition, wherein the composition in each region is different to compositions in other regions. FIG. 7 is a representation 700 of such an arrangement. In the embodiment of FIG. 7, three regions 701, 702, 703 are illustrated for simplicity. However, there is no limit to the number, size and shape of the sections used. The person skilled in the art will recognise that a large number of different arrangements of regions that are within the scope of the present disclosure. In the embodiment of FIG. 7, the first region 701 has a first composition of semiconductors, the second region 702 has a second composition and the third region 703 has a third composition. Any of the combinations of semiconductors previously described may be used in such an array. In an embodiment, the light emitting elements have addressable functionality. In an embodiment, the regions may operate at the same time or at different times.

The disclosure further provides a method of manufacturing light emitting elements and light emitting element arrays according to previous embodiments. A growth technique is provided that provides multiple static meta-surfaces, for which the optical functionalities will be encoded at wafer level and will differ from each other. In embodiments, single or multiple growth runs are used to deposit materials to provide for meta-elements with varying refractive indices. In an embodiment, wafer level integration of passive meta-optics with VCSELS is provided. Although VCSELs are likely to be the most important application, the person skilled in the art will appreciate that the techniques may be used for other applications. The semiconductor materials can be deposited using techniques such as Chemical Vapour Deposition (CVD), Metal Organic Chemical Vapour Deposition (MOCVD) or Plasma Enhanced Chemical Vapour Deposition (PECVD). Refractive index adjustability will simply be achieved by changing composition of meta-surfaces prior to material deposition. Meta-surfaces can be patterned using standard electron beam lithography techniques afterwards. The technique can be used with both top and bottom emitting VCSEL structures.

In embodiments, the respective metasurfaces are fabricated on respective light emitting surfaces of the light emitting elements. This disposition of the metasurface may be combined with any of the described embodiments.

Both single step and multiple step material deposition may be used according to the desired meta-elements. If a single composition is required, as, for example, in the embodiments of FIGS. 3 and 5 above, a single material deposition and fabrication run is used. If a variation in the compositions across an array is required, then multi-step deposition and fabrication runs may be performed. This may include masking of different sections of the array according to the material being deposited.

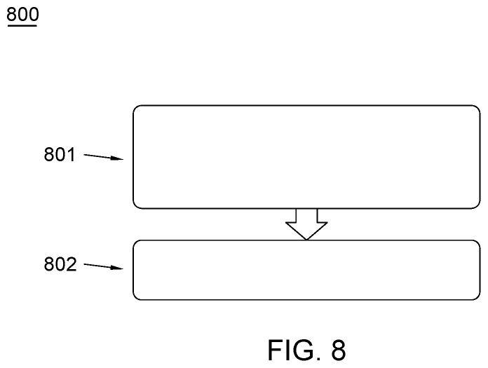

FIG. 8 is a flow chart 800 of a method of manufacture according to an embodiment. The flow chart illustrates a simplified example of the process of deposition according to an embodiment. A first step 801 comprises using chemical vapour deposition to apply a layer of semiconductor alloy with a first composition to a light emitting element. In an embodiment the deposition may be performed by Metal Organic Chemical Vapour Deposition (MOCVD). In another embodiment, it may be performed by Plasma Enhanced Chemical Vapour Deposition (PECVD). A meta-surface is then fabricated 802 in the semiconductor layer. In an embodiment, this latter step may be performed by electron beam lithography. In another embodiment, it may be performed by optical lithography.

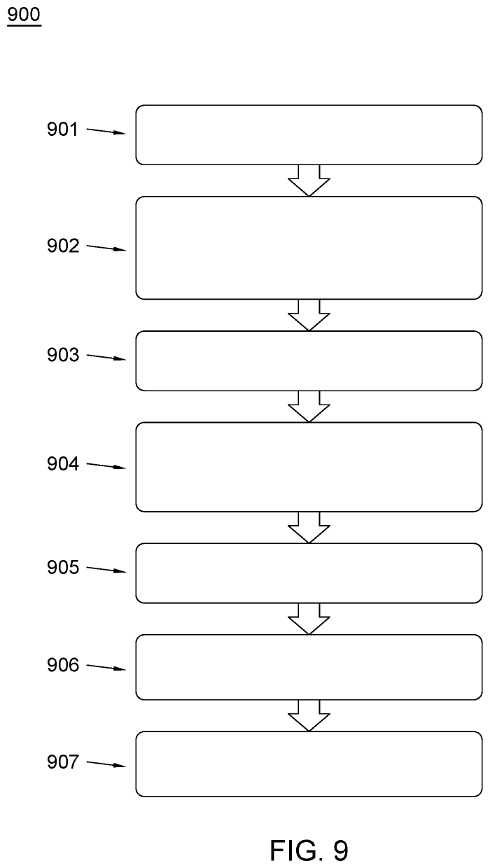

FIG. 9 is a flow chart 900 of a method of manufacture of a light emitting element array according to an embodiment. Each light emitting element comprises a meta-surface. The method comprises, prior to the step of using chemical vapour deposition to apply a layer of semiconductor alloy, masking 901 one or more light emitting elements in the array. The next step comprises, using 902 chemical vapour deposition to apply a layer of semiconductor alloy with a first composition to one or more light emitting elements. After using chemical vapour deposition to apply the layer of semiconductor alloy, the next step comprises unmasking 903 the masked one or more light emitting elements, followed by masking 904 one or more of previous unmasked light emitting element in the array. A second semiconductor alloy with a second composition different from the first composition is then applied 905. In an embodiment the deposition may be performed by Metal Organic Chemical Vapour Deposition (MOCVD). In another embodiment, it may be performed by Plasma Enhanced Chemical Vapour Deposition (PECVD). The masked light emitting elements are then unmasked 906, and a meta-surface is then fabricated 907 in the semiconductor alloy. In an embodiment, this latter step may be performed by electron beam lithography. In another embodiment, it may be performed by optical lithography.

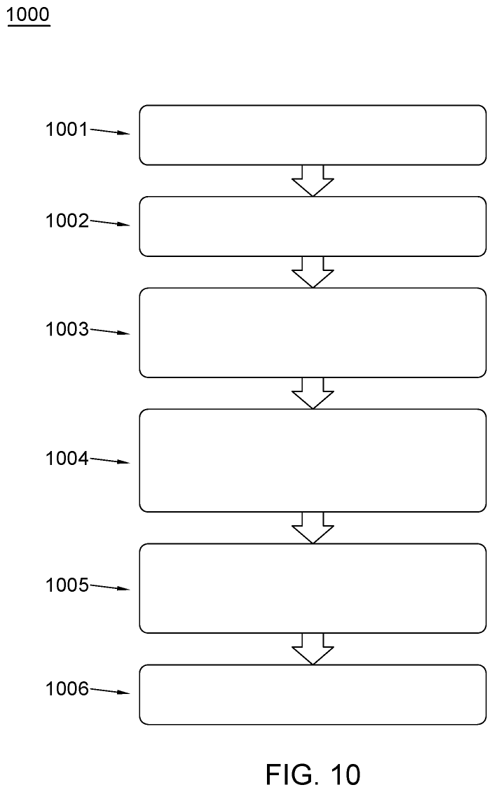

FIG. 10 is a flow chart 1000 of a method of manufacture of a light emitting element array according to an embodiment. The method comprises dividing 1001 the light emitting array into a plurality of regions, selecting 1002 for each region a semiconductor alloy with a composition, wherein each region is assigned a semiconductor alloy comprising a composition different from every other region. Next, for each region, light emitting elements which are not in the region are masked 1003. Using chemical vapour deposition a layer of semiconductor alloy is applied 1004 to light emitting elements in the region. Finally, the elements not in the region are unmasked 1005. In an embodiment the deposition may be performed by Metal Organic Chemical Vapour Deposition (MOCVD). In another embodiment, it may be performed by Plasma Enhanced Chemical Vapour Deposition (PECVD). A meta-surface is then fabricated in the semiconductor alloy 1006. In an embodiment, this latter step may be performed by electron beam lithography. In another embodiment, it may be performed by optical lithography.

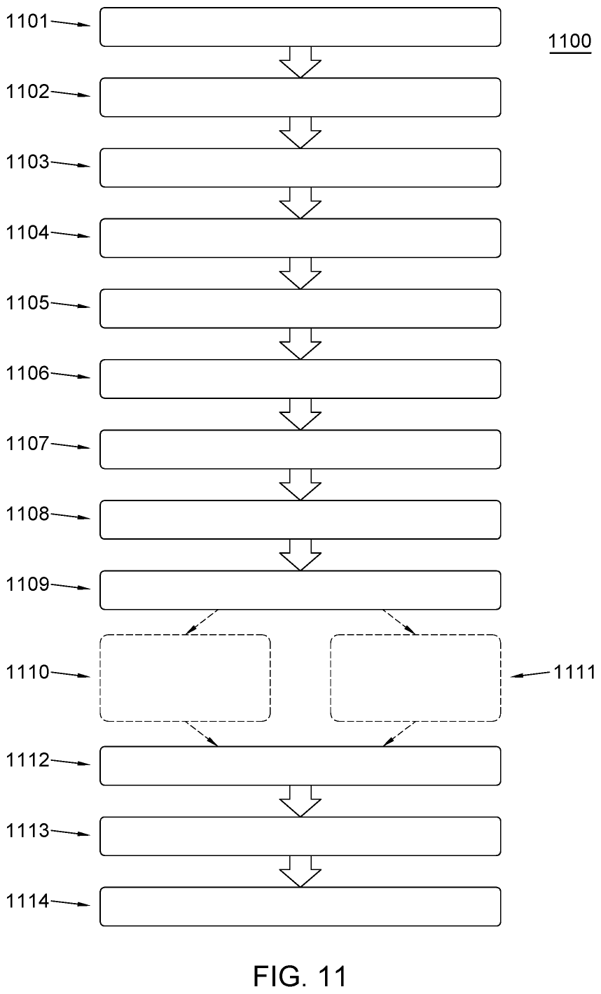

FIG. 11 is a flowchart 1100 of a method of manufacture of a VCSEL array according to an embodiment. The process begins with an EPI wafer 1101, upon which Silicon Oxynitride is deposited 1102. After planarization 1103, a P-electrode is formed 1104, followed by a mesa etch 1105, aperture oxidation 1106, backside polishing 1107 and the formation of an N-electrode 1108. After the completion of the VCSELs in the array, the meta-surfaces are formed by meta-surface deposition 1109 and fabrication 1112. As described above, the step of deposition may involve a single step deposition 1110 or a multi-step deposition 1111. After fabrication of the meta-surfaces 1112, wafer testing 1113 is implemented, followed by singulation and packaging 1114.

The skilled person will understand that in the preceding description and appended claims, “comprising” does not exclude other elements or steps, that “a” or “an” does not exclude a plurality, that a single unit may fulfil the functions of several means recited in the claims, and that features recited in separate dependent claims may be advantageously combined. Any reference signs in the claims should not be construed as limiting the scope.

Although the disclosure has been described in terms of particular embodiments as set forth above, it should be understood that these embodiments are illustrative only and that the claims are not limited to those embodiments.

For example, although an example of a light emitting element has been described, the techniques may also be applied to a light detecting element.

Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

### LIST OF REFERENCE NUMERALS

100 Meta-surface
101 Nano-pillar
200 Illumination device
201 VCSEL
202 Substrate
203 Microlens
204 Deflected light
205 Divergent illumination beam
300 Single VCSEL arrangement
301 VCSEL
302 Metasurface
303 Emitted light
400 VCSEL array
401 Substrate
402 VCSEL
403 VCSEL
404 VCSEL
405 VCSEL
406 VCSEL
407 Metasurface
408 Metasurface
409 Metasurface
410 Metasurface
411 Metasurface
500 VCSEL array
501 Dot representing VCSEL with metasurface
600 VCSEL array
601 Dot representing VCSEL with metasurface
602 Dot representing VCSEL with metasurface
603 Dot representing VCSEL with metasurface
700 VCSEL array
701 Dot representing VCSEL with metasurface
702 Dot representing VCSEL with metasurface
703 Dot representing VCSEL with metasurface
800 Flowchart
801 Using chemical vapour deposition to apply a layer of semiconductor alloy
802 Fabricating metasurface
900 Flowchart
901 Masking one or more light emitting elements in the array
902 Using chemical vapour deposition to apply a layer of semiconductor alloy
903 Unmasking the masked one or more light emitting elements
904 Masking one or more light emitting elements in the array
905 Using chemical vapour deposition to apply a layer of semiconductor alloy
906 Unmasking the masked one or more light emitting elements
907 Fabricating metasurface
1000 Flowchart
1001 Dividing the light emitting array into a plurality of regions
1002 Selecting for each region a semiconductor alloy with a composition
1003 Masking light emitting elements which are not in the region
1004 Using chemical vapour deposition a layer of semiconductor alloy
1005 Unmasking elements not in the region are unmasked
1006 Fabricating metasurface
1100 Flowchart
1101 EPI wafer
1102 Silicon Oxynitride is deposited
1103 Planarization
1104 P-electrode is formed
1105 Mesa etch
1106 Aperture oxidation
1107 Backside polishing
1108 Formation of an N-electrode
1109 Meta-surface deposition
1110 Single step deposition
1111 Multi-step deposition
1112 Fabrication
1113 Wafer testing
1114 Singulation and packaging

What is claimed is:

1. A light emitting element comprising a meta-surface, wherein the meta-surface comprises a semiconductor alloy of a first semiconductor and a second semiconductor, wherein a composition defines relative amounts of the first semiconductor and the second semiconductor in the alloy, and wherein the semiconductor alloy has a first composition.

2. A light emitting element according to claim 1, wherein the first semiconductor is one of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (Pb Se), Tellurium Selenide (TeSe), or Gallium Arsenide (GaAs), and wherein the second semiconductor is another of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (Pb Se), Tellurium Selenide (TeSe), or Gallium Arsenide (GaAs), the second semiconductor being different from the first semiconductor.

3. A light emitting element according to claim 1, wherein the semiconductor alloy comprises a third semiconductor and the first composition defines the relative amounts of the first semiconductor, second semiconductor and third semi-conductor in the alloy.

4. A light emitting element according to claim 3, wherein the third semiconductor is one of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (Pb Se), Tellurium Selenide (TeSe), or Gallium Arsenide (GaAs), and wherein the third semiconductor is different from the first semiconductor and the second semiconductor.

5. A light emitting element according to claim 1, comprising a vertical cavity surface emitting laser.

6. A light emitting element according to claim 1, wherein the metasurface is disposed on a light emitting surface of the light emitting element.

7. A light emitting array comprising a plurality of light emitting elements according to claim 1.

8. A light emitting array according to claim 7,
comprising a first light emitting element and at least one second light emitting element having a second composition different from the first composition.

9. A light emitting array according to claim 8, comprising a plurality of regions, wherein each region comprises light emitting elements with metasurfaces with a single composition, wherein the composition in each region is difference to compositions in other regions.

10. A light emitting array according to claim 9, wherein the regions are configured to provide structured illumination onto a pre-defined scene.

11. A method of manufacturing a light emitting element with a meta-surface, the method comprising the steps of:
using chemical vapour deposition to apply a layer of semiconductor alloy, wherein the semiconductor alloy comprises a first semiconductor and a second semiconductor, and wherein a composition defines relative amounts of the first semiconductor and the second semiconductor in the alloy, and wherein the semiconductor alloy has a first composition; and
fabricating a meta-surface in the alloy.

12. A method according to claim 11, wherein the metasurface is fabricated on a light emitting surface of the light emitting element.

13. A method according to claim 11, further comprising manufacturing a light emitting array comprising a plurality of light emitting elements, each light emitting element comprising a meta-surface, the method further comprising:
prior to the step of using chemical vapour deposition to apply a layer of semiconductor alloy, masking one or more light emitting element in the array;
after using chemical vapour deposition to apply the layer of semiconductor alloy, unmasking the masked one or more light emitting elements;
masking one or more of previous unmasked light emitting element in the array; and
applying a second semiconductor alloy with a second composition different from the first composition;
unmasking the masked light emitting elements; and
fabricating a meta-surface in the alloy.

14. A method according to claim 13, further comprising dividing the light emitting array into a plurality of regions, selecting for each region a semiconductor alloy with a composition, wherein each region is assigned a semiconductor alloy comprising a composition different from every other region; and
for each region:
masking light emitting elements which are not in the region;
using chemical vapour deposition to apply the layer of semiconductor alloy to light emitting elements in the region;
unmasking the elements not in the region; and
fabricating meta-surfaces in the alloy.

15. A method according to claim 11, wherein the first semiconductor is one of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (PbSe), Tellurium Selenide (TeSe), or Gallium Arsenide (GaAs), and wherein the second semiconductor is another of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (Pb Se), Tellurium Selenide (TeSe), or Gallium Arsenide (GaAs), the second semiconductor being different from the first semiconductor.

16. A method according to claim 11, wherein the semiconductor alloy comprises a third semiconductor, wherein the third semiconductor is one of Germanium (Ge), Silicon (Si), Tin (Sn), Germanium Silicon (GeSi), Germanium Tin (GeSn), Silicon Tin (SiSn), Selenium (Se), Lead (Pb), Tellurium (Te), Lead Telluride (PbTe), Lead Selenide (Pb Se), Tellurium Selenide (TeSe), or Gallium Arsenide (GaAs), and wherein the third semiconductor is different from the first semiconductor and the second semiconductor.

17. A method according to claim 11, wherein chemical vapour deposition is performed using one of Metal Organic Chemical Vapour Deposition (MOCVD) or Plasma Enhanced Chemical Vapour Deposition (PECVD).
